(19) United States
(12) Patent Application Publication
(10) Pub. No.: US 2026/0074483 A1
(43) Pub. Date: Mar. 12, 2026

(54) Compact Laser Assembly For Reverse On-PCB Direct-Coupling

(71) Applicant: Ciena Corporation, Hanover, MD (US)

(72) Inventors: Raphaël Beaupré-Laflamme, Québec (CA); Claude Gamache, Gatineau (CA)

(73) Assignee: Ciena Corporation, Hanover, MD (US)

(21) Appl. No.: 18/828,072

(22) Filed: Sep. 9, 2024

(51) Int. Cl. H01S 5/0239; H01S 5/02253; H01S 5/02255; H01S 5/02325; H01S 5/024; H01S 5/068

(52) U.S. Cl. CPC H01S 5/0239; H01S 5/02253; H01S 5/02255; H01S 5/02325; H01S 5/02415; H01S 5/068

(57) ABSTRACT

A laser assembly is provided. The laser assembly includes a printed circuit board; a laser sub-assembly including a thermo-electric cooler and an optical train, wherein the laser sub-assembly is configured to connect to the printed circuit board such that the optical train is disposed between the printed circuit board and the thermo-electric cooler, wherein the thermo-electric cooler is configured to extract heat from the optical train outwardly from the printed circuit board, and wherein the laser assembly is configured to connect optically with a photonic integrated circuit via free space. Advantageously, the laser assembly includes a top-down approach where the thermo-electric cooler radiates heat outward, supports a pre-assembled approach, and uses free space connectivity for the laser path to the photonic integrated circuit, i.e., no fiber connections.

### FIELD OF THE DISCLOSURE

The present disclosure relates generally to optical devices. More particularly, the present disclosure relates to a compact laser assembly for reverse on-printed circuit board (PCB) direct-coupling.

### BACKGROUND OF THE DISCLOSURE

Optical communication, which refers to transmitting information while using light as the medium, is a preferred method of building networks. In the current state of optical communication technology, there is a drive for pluggable optical modules and other types of sub-assemblies which are compact in size, and which are used in network devices, such as routers, switches, computing platforms, etc. In such pluggable optical modules and other types of sub-assemblies, optical components such as transmitters and modems frequently rely on the use of optical fibers for connectivity, such as lasers to photonic integrated circuits. Although these fibers are effective at transmitting and guiding light, they introduce several challenges as far as complexity and cost of manufacturing, especially given the compact sizes of pluggable optical modules and other types of sub-assemblies.

### BRIEF SUMMARY OF THE DISCLOSURE

The present disclosure relates to systems and methods for fiber optics and networking communications. More specifically, the present disclosure provides methods and devices which remove the necessity for some optical fibers in pluggable optical modules and other types of sub-assemblies (“pluggable sub-assemblies”). The present disclosure provides devices and methods for directly coupling optics such as lasers into the photonic integrated circuit, via free space. Example devices can include a subassembly of one or more lasers coupled with one or more thermo-electric coolers. The thermo-electric coolers can function as an optical bench on which the laser can be aligned. The laser can be coupled with a ceramic carrier, a collimating lens, and an isolator. Such a device can be assembled on a printed circuit board main assembly, notably with the thermo-electric cooler disposed away or on top of the assembly. The device can be aligned with a photonic integrated circuit and can be functionally coupled therewith.

The assembly process for incorporating optical fibers into such pluggable sub-assemblies is labor intensive and prone to issues such as fiber breakage. In particular, polarization-maintaining fibers, which are notably expensive, are prone to breakage in use which makes them a significant cost when considering the production of optical devices. Additionally, the process of aligning optical fibers with photonic integrated circuits requires precision and is susceptible to alignment errors, which can compromise the optical performance of the system. To address some of these challenges, significant attention has been shown in eliminating optical fiber couplings in favor of directly coupling optical sources such as lasers to photonic integrated circuit waveguides. Such approach could potentially reduce the amount of fibers used, decrease manufacturing costs, and simplify the assembly process. However, the direct coupling technique brings a further set of challenges including for example the need for precise alignment and opto-mechanical stability. Moreover, the light sources used require careful thermal management and a reliable power supply which can complicate their integration with photonic integrated circuitry.

One of the significant constraints in achieving direct couplings is the design of the printed circuit board to which the photonic integrated circuit and optical sources are mounted. Traditional solutions, such as creating cavities in the board or shortening the length of the board are more sensitive to mechanical stress. In addition to the mechanical challenges, thermal management remains a critical issue. The power dissipation capacity of current optical devices is often limited and suffers from thermal bias. For applications requiring multiple frequencies, fibered laser systems necessitate complex and costly configurations. These current state of the art defines a significant need in terms of cost effect, efficiency, and more compact optical communication devices which is not yet met. Thus, there remains a clear need for compact laser assemblies for on-PCB (Printed Circuit Board) direct coupling.

Accordingly, one aspect of the present disclosure pertains to a laser assembly, the laser assembly Including a printed circuit board; and a laser sub-assembly including a thermo-electric cooler and an optical train, wherein the laser sub-assembly is configured to connect to the printed circuit board such that the optical train is disposed between the printed circuit board and the thermo-electric cooler, wherein the thermo-electric cooler is configured to extract heat from the optical train outwardly from the printed circuit board, and wherein the laser sub-assembly is configured to connect optically with a photonic integrated circuit via free space.

Another aspect of the present disclosure pertains to a laser assembly formed by a process of pre-assembling a laser sub-assembly including at least one thermo-electric cooler and at least one optical train; coupling the laser sub-assembly to a lid; coupling the pre-assembled laser sub-assembly on the lid to the printed circuit board, such that the optical train is disposed between the printed circuit board and the thermo-electric cooler; and optically coupling the laser sub-assembly to a photonic integrated circuit via free space; wherein the thermo-electric cooler is configured to extract heat from the optical train outwardly from the printed circuit board.

In yet another aspect, the present disclosure generally relates to a laser device, the laser device comprising a substantially rigid lid comprising a wall portion and a plate portion, the lid defining a hollow interior containing therein an optical train, the optical train comprising a laser emitter and a thermo-electric cooler disposed superjacent to the lid, the thermo-electric cooler is configured to define a heat transfer path extending upwardly from the lid.

### BRIEF DESCRIPTION OF THE DRAWINGS

The present disclosure is detailed through various drawings, where like components or steps are indicated by identical reference numbers for clarity and consistency.

FIG. 1A is a schematic view of a laser assembly for on-PCB direct coupling in accordance with one aspect of the present disclose.

FIG. 1B is a schematic view of the laser assembly of FIG. 1A depicting a periscope in continuing accordance with one aspect of the present disclosure.

FIG. 1C is a schematic view of the laser assembly of FIGS. 1A & 1B depicting a common stiffening substrate on the printed circuit board in continuing accordance with one aspect of the present disclosure.

FIG. 2 is an isometric view of a lid in accordance with an aspect of the present disclosure.

FIG. 3A is a bottom view of an optical train coupled to a thermo-electric cooler in accordance with yet another aspect of the present disclosure.

FIG. 3B is a bottom view of the optical train coupled to the thermo-electric cooler of FIG. 3A depicting further assembly of the optical train.

FIG. 4A is a top view of the optical train and thermo-electric cooler of FIGS. 3A & 3B coupled with the lid of FIG. 2 in continuing accordance with the present disclosure.

FIG. 4B is a perspective view of the optical train and thermo-electric cooler of FIG. 4A coupled with a photonic integrated circuit in accordance with another aspect of the present disclosure.

FIG. 5A is a schematic view of a pair of thermo-electric coolers prior to an alignment in accordance with yet another aspect of the present disclosure.

FIG. 5B is a schematic view of the pair of thermo-electric coolers with an adhesive disposed on a top portion thereof in accordance with an aspect of the instant disclosure.

FIG. 6A is a schematic view of the pair of thermo-electric coolers of FIG. 5A with a lid installed.

FIG. 6B is a schematic view of the pair of thermo-electric coolers of FIG. 5A after the establishment of a coplanar surface.

FIG. 7 is a schematic view of an alternative embodiment of a laser assembly in accordance with one aspect of the present disclosure.

FIG. 8 is a flow chart for a process to create a laser assembly in accordance with an aspect of the present disclosure.

### DETAILED DESCRIPTION OF THE DISCLOSURE

Again, the present disclosure generally relates to optics and laser devices, e.g., a laser assembly. The laser assembly can include one or more lasers coupled to one or more thermo-electric coolers. The thermo-electric coolers can be structured to function as an optical bench on which laser assembly or a portion thereof can be aligned. The laser assembly can include an optical train which can include a laser chip, a ceramic carrier, a first collimating lens, and an isolator. The laser assembly can include a lid. The lid can include a wall portion and a flat plate. The flat plate can serve as an additional optical bench and can be configured to participate in optical alignment. Advantageously, the lid allows the optical train to be placed between the thermo-electric cooler and the printed circuit board.

It is envisioned that some embodiments can be mounted “top down” onto a printed circuit board, for example by adhesion. Importantly, in such a configuration, the thermo-electric cooler can be disposed upwardly and can extend away from the printed circuit board, and while disposed extending away from the printed circuit board, the thermo-electric cooler can define a heat transfer path which beneficially extends away from the printed circuit board. Conventionally, having the thermo-electric cooler (TEC) on or at the PCB requires some mechanism to dissipate heat. In some aspects, the optical train can include at least one focusing lens. The optical train can define a laser path, and the focusing lens can be disposed in the optical train. A photonic integrated circuit can be included in the optical train, and more specifically in the laser path such that a laser emission can impinge the photonic integrated circuit. The lens can be aligned with the photonic integrated circuit.

In typical aspects, any portion of the device of the present disclosure can be preassembled. As used herein, the term “pre-assembled” generally refers to a portion of a laser device, laser assembly, or optical device which has been fully or partially constructed and optionally aligned before they are combined with another assembly. For example, only the optical train can be pre-assembled prior to installation in the laser assembly. Any portion of the device described herein can be assembled to require certain surfaces of certain components to extend in a certain direction. For example, the laser assembly can be assembled “top down” onto the printed circuit board, wherein “top down” generally defines the optical train proximal to the printed circuit board and the thermo-electric cooler distal to the printed circuit board. The laser assembly can include the optical train and the thermo-electric cooler, wherein the thermo-electric cooler defines the top portion, and the optical train defines the bottom portion. Such an arrangement can define the heat transfer path and can modulate heat outwardly away from the printed circuit board and optical train in an upward direction (relative to the printed circuit board).

Some aspects of the device include the lid portion. The lid portion can serve as a secondary optical bench for final alignment of the laser assembly. Further, the lid can include the plate portion which can be a structural member. The lid, and more specifically the plate portion can be substantially resilient and resist warpage of the optical train due to printed circuit board softness. The final alignment can include focusing the lens to directly couple optical train with the photonic integrated circuit. The laser assembly can include a plurality of optical trains. The plurality of optical trains can be independently temperature controlled. Such independent control can tune the wavelength of laser light emitted from each optical train. The independent control of each optical train can allow for increased accuracy and allow independently controlled high optical power. In general, the optical train can include at least a laser emitter, a carrier, the thermo-electric cooler, and one or more passive or active optical components. In several aspects, the device can be formed of or include materials which define a thermal expansion coefficient or alpha coefficient.

One or more components of the laser assembly can be selected such that the thermal expansion is effectively substantially similar. Further, one or more components of the laser assembly can be selected such that the ultimate thermal expansion is substantially similar. As such, the total displacement of the one or more components of the laser assembly can be substantially similar under thermal loading. Critically, as a result of the one or more components of the device of the present disclosure having similar thermal expansion and/or thermal expansion coefficients, the displacement from thermal expansion may not shift the components of the device out of optical alignment. In some aspects, the laser assembly can be pre-assembled with a lid. The lid can be used to couple one or more thermo-electric coolers during the assembly phase. Moreover, by way of the lid, small vertical misalignments can be corrected. For example, the lid can define a flat surface, wherein the flat surface defines one or more distances between the one or more thermo-electric coolers. The difference distances can be filled with an adhesive underneath the thermo-electric cooler which can homologate the distances relative to the lid.

In various embodiments, the laser assembly described herein includes a printed circuit board. The printed circuit board can be a bottom portion of the laser assembly. The bottom portion can define the lowermost section of the laser assembly wherein the laser assembly extends upwardly therefrom. The laser assembly can include a thermo-electric cooler. The thermo-electric cooler can define a top portion of the laser assembly and can be disposed superjacent to the printed circuit board. As defined herein, the thermo-electric cooler can be the highest portion of the laser assembly. The laser assembly can include an optical train. The optical train can include a lid and a laser emitter and can be configured for optical signal emission. The optical train can be disposed in between the bottom printed circuit board and the top thermo-electric cooler. Advantageously, the laser assembly can be assembled with such a top-down approach. Wherein the thermo-electric cooler is the top portion of the laser assembly and the printed circuit board is the bottom most portion of the laser assembly.

An advantageous arrangement where heat is extracted outwards from the assembly, not at the bottom at the PCB. The laser assembly of the present device can define a temperature gradient across the device which encourages heat transfer from the bottom portion or printed circuit board towards the top. More generally, heat can be extracted upwardly from the printed circuit board towards the thermo-electric cooler. The thermo-electric cooler can define a heat transfer path which thermally isolates the laser sub-assembly from the PCB as much as possible and terminates past the top portion of the thermo-electric cooler. A further advantage of the laser assembly includes the pre-assembly of the laser sub-assembly. The laser sub-assembly or any portion thereof can be constructed, fabricated, or tested prior to being combined with the laser assembly. Further, it is envisioned that the laser sub-assembly can be partially pre-assembled, constructed, fabricated, or tested prior to being combined with the laser assembly. The laser sub-assembly can be created at a different location or produced in volume before being provided to the laser assembly. A yet further advantage of the laser assembly of the present disclosure is the lowered need for fiber connections. In some aspects, the optical train or any portion thereof can be optically coupled to the photonic integrated circuit, for example via free space. A laser path can extend through free space. By way of using free space and/or direct optical coupling, there is no need for fiber splices, fiber connectors, or fiber loops which can be complicated, difficult to manage, and sensitive to disturbances.

### § 1.1 Laser Assembly Structure

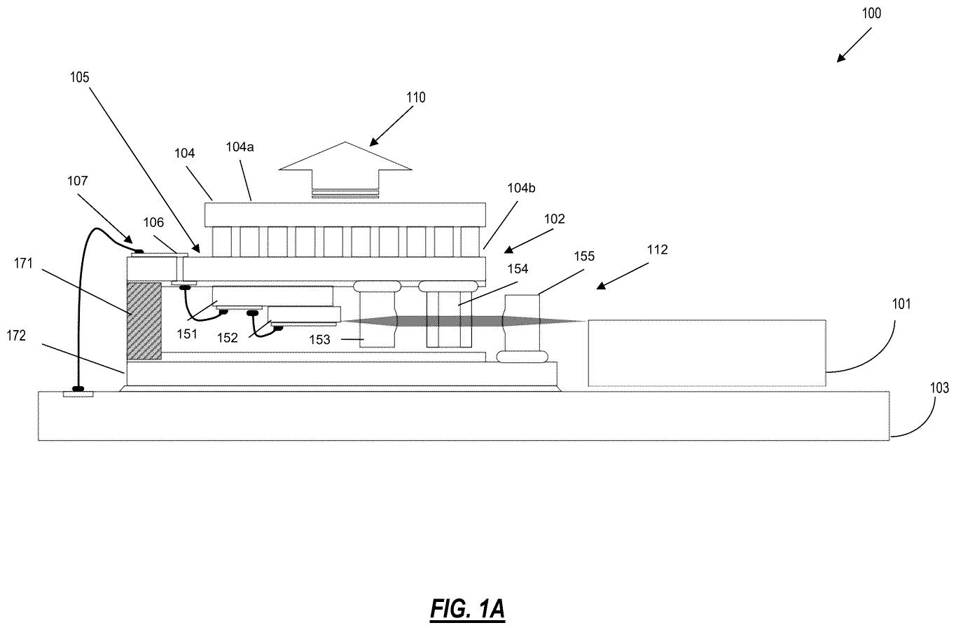

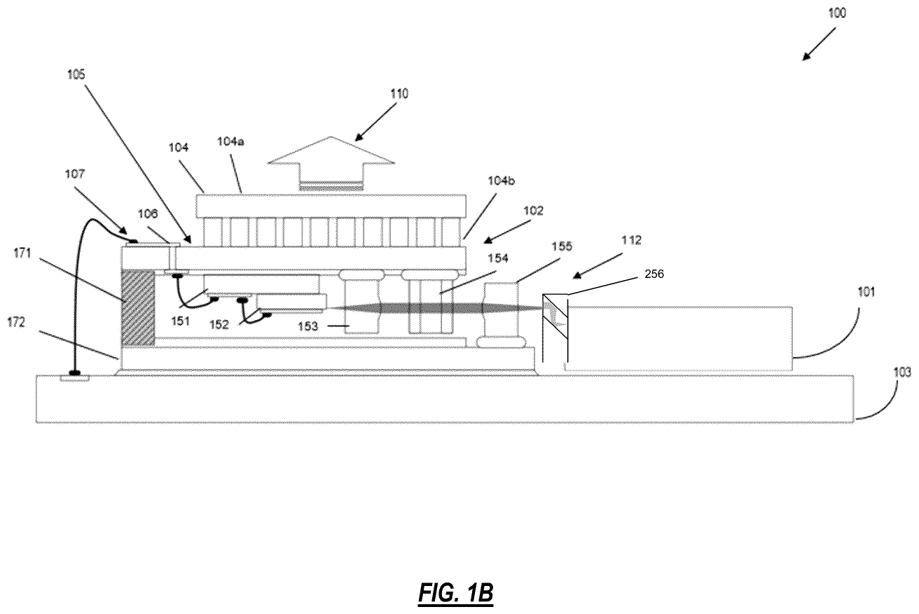

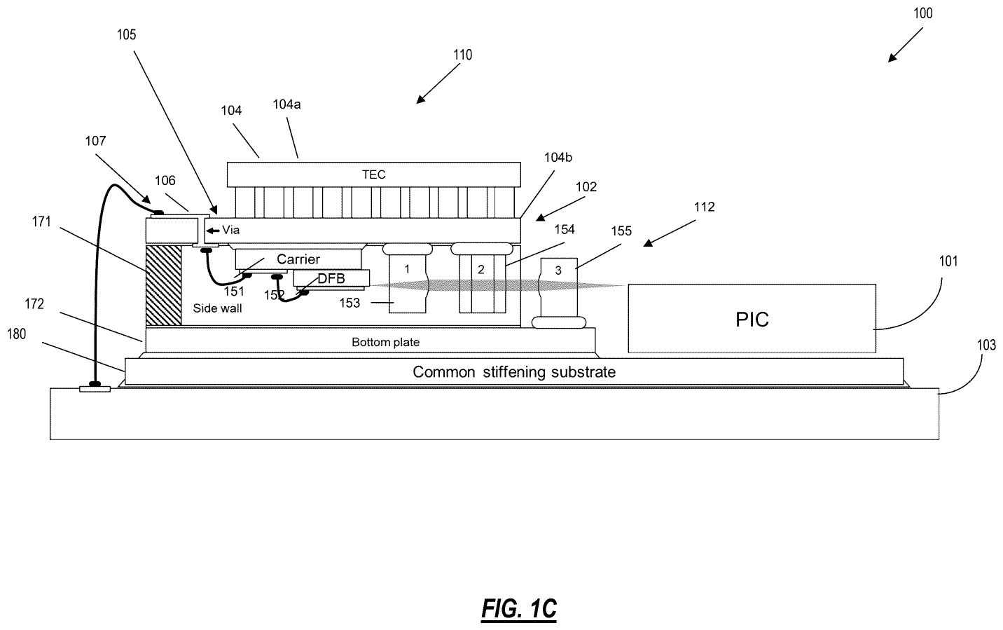

Turning now to FIGS. 1A, 1B & 1C, a schematic view of a laser assembly 100 in accordance with the present disclosure is shown and described. The laser assembly 100 can include a photonic integrated circuit (PIC) 101. The PIC 101 can be an optical integrated circuit operable with light-based signals, such as laser signals from a laser emitter and can be configured to perform functions such as signal processing, computation, or the like. The PIC 101 can be a type of semiconductor device which is operable to integrate multiple photonic functions, such as light generation, modulation, signal processing, or the like onto a single chip. In some aspects, the PIC 101 is a silicon photonics (SiPh) PIC 101, although other types such as Indium Phosphide (InP) and Silicon Nitride (SiN) are contemplated. The PIC 101 can be incorporated into a fiber-optic network. The PIC 101 can be in optical communication with a laser sub-assembly 102. The laser sub-assembly can generally be configured as an optical source, for example a laser light source. The laser sub-assembly 102 can be disposed on a printed circuit board (PCB) 103 or a portion thereof. More generally the PCB 103 can be subjacent to the laser sub-assembly 102. Further the PIC 101 can be disposed on a portion of the PCB 103. It is envisioned that the laser sub-assembly 102 and the PIC 101 can be disposed axially from each other and define an axis about a surface of the PCB 103. The laser assembly 100 can include a thermo-electric cooler (TEC) 104. The TEC 104 can be a device configured to control and stabilize the temperature of components, for example laser diodes or optical trains. The TEC 104 can be a device which operates based on the Peltier effect. More generally the TEC 104 can create a temperature difference based on a passing current. The TEC 104 can be operable to provide targeted heat transfer or directed heat transfer. The TEC 104, when an electric current passes therethrough, can define a hot side and a cold side. In some aspects, the TEC 104 can include a heatsink, a fan, or a plurality of heat fins. The TEC can define a top 104a and a bottom portion 104b. The PCB 103 can include, e.g., a Printed Circuit Board Assembly (PCBA), a High Density Build-Up (HDBU), a Substrate Like PCB (SLP), and other variants.

The bottom portion 104b of the TEC 104 can engage with an optical train 105. The optical train 105 can be any collection of optical components, both passive and active, which can provide a light source, such as a laser light source. The optical train 105 can be a sequence of optical devices in partial or full axial alignment. In typical aspects, the optical train 105 can generate heat during use. The combination of the TEC 104 with the optical train can provide heat transfer from the optical train 105. Importantly, the TEC 104, as a result of being mounted superjacent to the optical train 105 against the bottom portion 104b of the TEC 104 can define a heat transfer path 110. The heat transfer path 110 can be a direction of heat transfer. More specifically, the heat transfer path 110 can be a route through which thermal energy travels. The optical train 105 can be a heat source or hot side and the TEC 104 can be a heat sink or cold side. It is envisaged that the heat transfer path 110 can define a conduction path, a convection path, an advection path, or a radiation path. Importantly, the heat transfer path 110 can extend away from the optical train 105 towards the top portion 104a of the TEC 104. More generally, the heat transfer path can be created by the combination of the optical train 105 and the TEC 104 and can direct heat transfer upwardly and away from the optical train 105, and more generally the laser assembly 100. The heat transfer path 110 extends outwardly from the printed circuit board, so heat is not added to any components thereon.

The optical train 105 can further include a VIC 106. The VIC 106 can be any passage configured to provide electrical communication between the optical train 105, or any portion of the laser assembly 100 and a power source. The VIC 106 can be configured to locate a power communication mechanism, such as a power cable. The VIC 106 can be a small opening in a portion of the laser assembly 100, for example, a lid 107. The optical train 105 can include a plurality of optical devices. Notably, the optical train generally includes a carrier 151, a laser emitter 152, a first lens 153, and an isolator 154.

Included in some embodiments, the carrier 151 can be a planar structure configured to engage the laser emitter 152. The carrier 151 can be formed of a ceramic material, such as and without limitation, aluminum nitride, beryllium oxide, alumina, silicon carbide, zirconia, silicon nitride, magnesium oxide, yttrium aluminum garnet, or suitable ceramic. The laser emitter 152 can be mounted on or a portion of the carrier 151. The carrier can be mounted to the lid 107, the TEC 104, or any portion of the laser assembly 100. The laser emitter 152 can be any device operable to produce a coherent or interrupted beam of light, such as laser light. More specifically, the laser emitter 152 can be a device which emits light through the process of stimulated emissions. The emitted light can define a narrow wavelength and high directionality. The laser emitter 152 can be a distributed feedback laser (DFB) laser, although other laser emitters, such as and without limitation, a Fabry-Perot laser, a vertical cavity surface emitting laser (VCSEL), a Neodymium-doped Yttrium aluminum garnet (Nd) laser, a quantum cascade laser (QCL), helium-neon (HeNe) laser, a fiber laser, or any laser emitter which can function in an optical circuit are contemplated. The optical train 105 can include the first lens 153. The first lens 153 can be a collimating lens. More generally, the first lens 153 can be an optical lens which can convert diverging or converging light into a parallel beam. The first lens 153 can also be configured to modify the laser light emitted from the laser emitter 152 to have minimal divergence or convergence. The optical train can include the isolator 154. The isolator 154 can be any device which can protect any component of the laser assembly 100 from unwanted feedback or reflections from the laser emitter 152. The isolator 154 can be configured to allow light to pass through in only a single direction. The optical train 105 can include the second lens 155. The second lens 155 can be a focusing lens. More generally, the second lens 155 can be an optical component configured to converge or focus the light emitted from the laser emitter 152 into a smaller point. The focusing lens 155 can be a convex or a convex lens.

The optical train 105 can further include a periscope 156. The periscope 156 can be any device which can redirect a laser emission. In some aspects, the periscope 156 can optionally be included in the optical train 105. The periscope 156 can include a plurality of reflective surfaces which can modify, such as translate, the laser emission direction. The laser emitter 152 can define a laser travel path 110. The laser travel path 110 can be an axial path over which an emission from the laser emitter travels. In some aspects, one or more components of the optical train can be disposed along the laser travel path 110. The laser travel path 110 can initiate at the laser emitter 152 and can terminate at the PIC 101. The inclusion of the periscope 156 is optional based on the requirements of the laser assembly 100. Further, the periscope 156 can be configured to correct for height mismatch and pitch mismatch between the optical train 105 and the PIC 101 or the optical train 105 and a chip plane.

In an aspect, the PIC 101 and the bottom plate 172 can be mounted on a common stiffening substrate 180 (FIG. 1C) to provide more support than the PCB 103. Here, the PCB 103 may flex, leading to problems after alignment. The common stiffening substrate 180 can maintain position over time and is stiffer than the PCB 103.

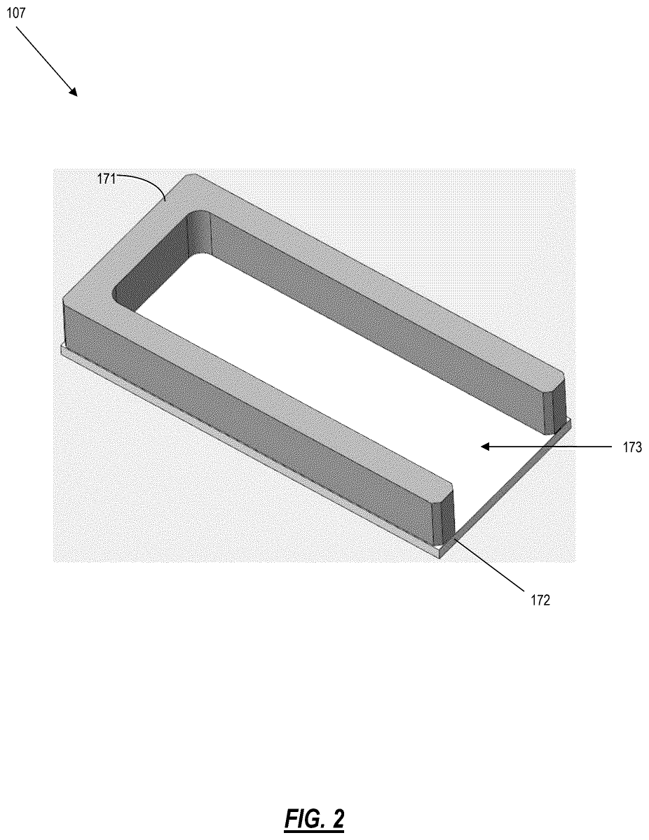

Turning now to FIG. 2, an isometric view of the lid 107 of FIG. 1 is shown and described. The laser assembly 100 can include a lid 107. The lid can be a structure configured to encase the optical train 105. The lid 107 can be formed of a monolithic unit or can be formed of two or more parts. The lid 107 can be substantially rectilinear, but other configurations are contemplated. The lid 107 can define a hollow interior 173 or cavity which can receive therein a portion of the laser assembly 100, such as the optical train 105. The lid can be formed of one or more materials and structured to provide support for any portion of the laser assembly 100. For example, the lid 107 can provide structural support for the optical train 105. In sone aspects, the lid 107 can define a side wall 171 and a lid 107. The side wall 171 can extend upwardly towards the top portion 104a of the TEC 104 from the bottom plate 172 and can define a boundary therearound. The side wall can be generally “U-shaped” or contiguous based on the configuration of the laser assembly 100. The bottom plate 172 can be a generally flat and planar solid member. In some aspects, the bottom plate 172 of the lid 107 can be configured to engage with the PCB 103 or a portion thereof. The optical train 105 can be protected and housed within the hollow interior 173 of the lid 107. The lid 107 or any portion thereof can be formed of low thermal conductivity materials, such as and without limitation, alumina and Enrico.

### § 1.2 Laser Operation

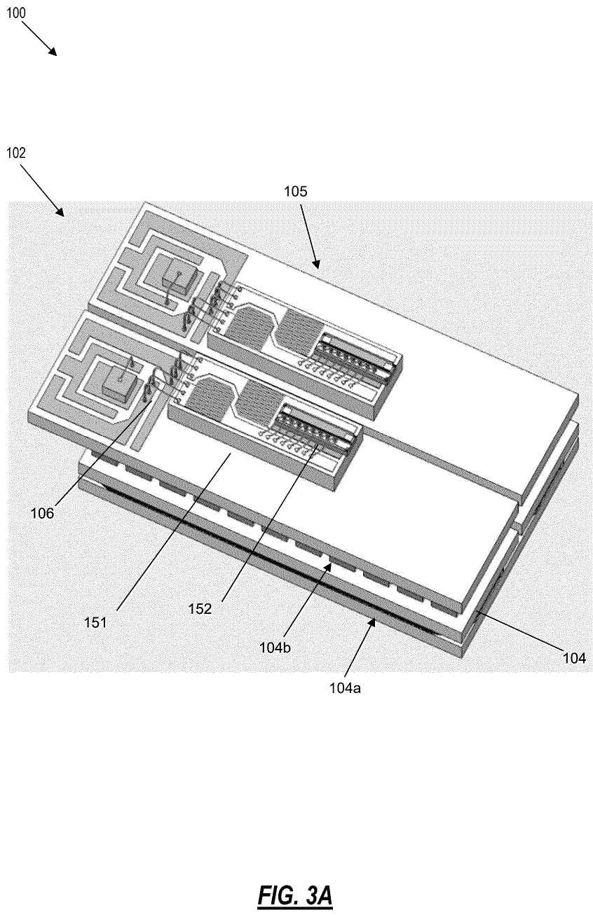

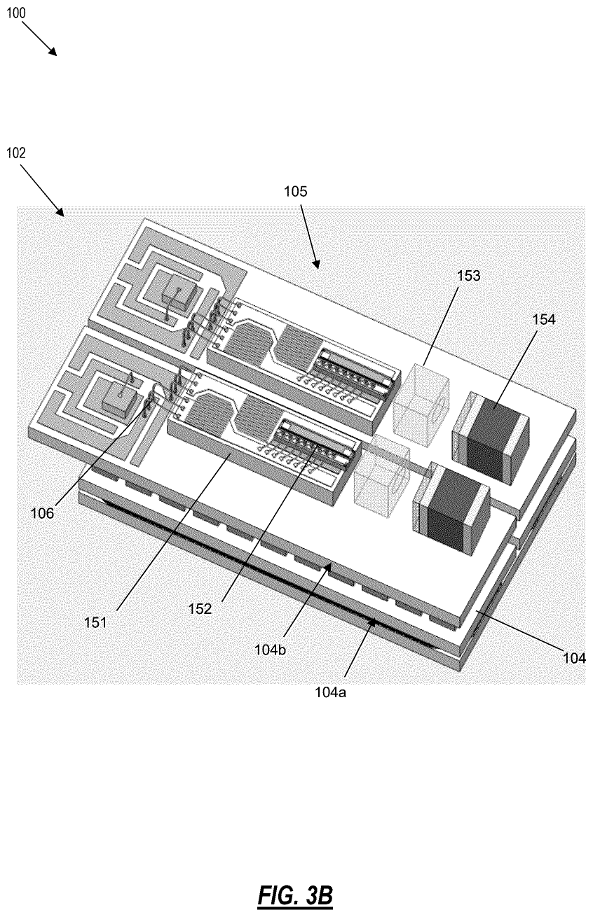

Turning now to FIGS. 3A & 3B, a bottom view of an optical train coupled to a thermo-electric cooler is shown and described. In some aspects, the laser assembly 100 can include a single optical train 105 and a single TEC 104 mounted onto the PCB 103. It is to be understood that the invention includes a variety of combinations of TECs 104 and optical trains 105. For example, as shown in FIG. 3A, the laser assembly 100 can include a pair of TECs 104 and a pair of optical trains 105. Further, FIG. 3B depicts the laser sub-assembly 102 from a bottom view. Some aspects of the laser sub-assembly 102 can be configured to reduce the optical fiber requirement, as the laser sub-assembly 102 can be configured to directly couple to the PCB 103. Advantageously, the reduction in the number of fiber loops or connections increases the efficiency and reliability of the circuit while lowering the cost. Further, the direct coupling of the laser sub-assembly 102 provides for precise alignment and opto-mechanical stability.

In typical aspects, the laser assembly 100 can include the laser sub-assembly 102 which can include one or more optical trains 105 coupled to one or more TECs 104. In addition to thermal management, the one or more TECs 104 can be structured and function as an optical bench. As used herein, the term “optical bench” generally refers to a structure defined by high stability and rigidity configured to minimize vibrations and mechanical instability. Moreover, the TEC 104, as a result of being configured as an optical bench, can assist in the optical train 105 alignment. For example, the TEC 104 can be an optical bench on which the initial optical train 105 alignment is performed. Further the optical train 105 can be initially aligned and cemented onto the TEC 104. More generally, the optical train 105 can be aligned by or on the TEC 104. In example only, and without limitation, the first lens 153 can be aligned with the isolator 154 while disposed on the TEC 104. The optical train 105 can be coupled to the TEC 104 on the bottom portion 104b. Further, as a result of the optical train 105 being configured to engage with the bottom portion 104b of the TEC 104, the laser sub-assembly 102 can encourage heat transfer in the heat transfer path 110 (shown in FIG. 1) as generally away from the optical train 105 and towards the top portion 104a of the TEC 104. As stated, the laser sub-assembly 102 can include any number of TECs 104 or optical trains 105.

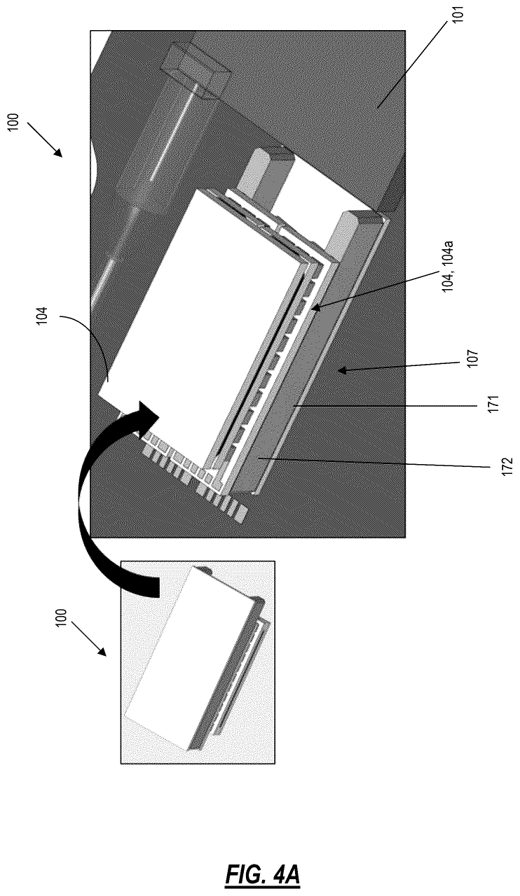

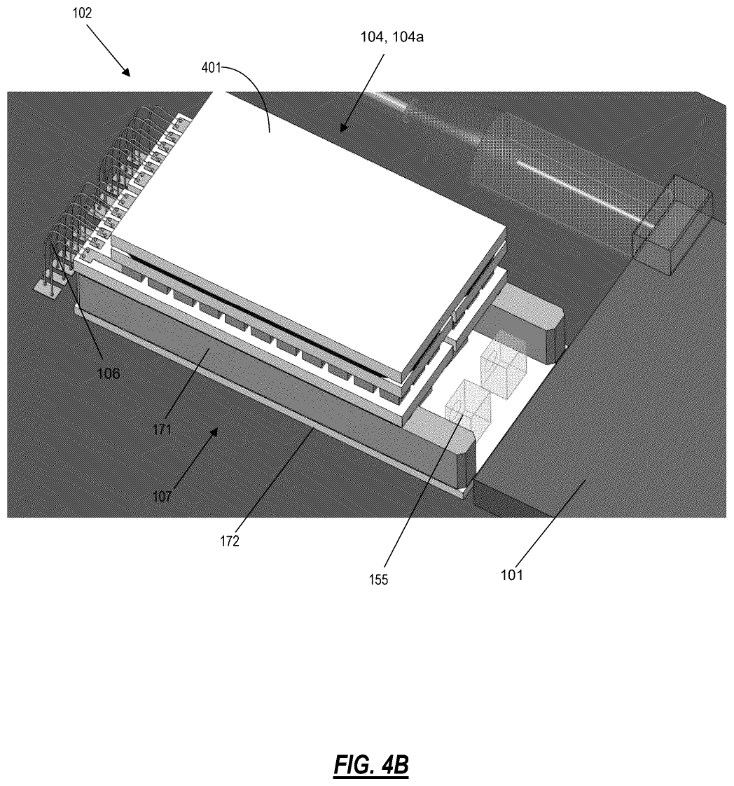

Turning now to FIGS. 4A & 4B, a top view of the laser sub-assembly 102 engaged with the PIC 101 is shown and described. The lid 107 is depicted as being engaged with the laser sub-assembly 102. As shown, the lid 107 can be configured to substantially encase the optical train 105, and more generally any portion of the laser sub-assembly 102. The lid 107, which includes the side wall 171 and the bottom plate 172 can function as an optical bench. In an example of operation, the bottom plate 172 of the lid 107 can be a second optical bench, on which a secondary optical alignment can be facilitated. The lid 107, or any portion of the laser sub-assembly 102 can be assembled via adhesion, for example with an adhesive. The adhesive can be an adhesive configured to use in photonics and fiber optics which can provide low absorption, thermal stability, and precision alignment. The adhesive can be a quick bond cement or a snap adhesive and can be configured to be either highly thermally conductive or thermally insulative, depending on the application. It is envisioned that the adhesive can be used, in addition to bonding one or more components of the laser sub-assembly 102 to create thermal barriers which either encourage or discourage heat transfer. Examples of such adhesives include, but are not limited to epoxy adhesives, UV-curing adhesives, acrylic adhesives, silicone adhesives, polyurethane adhesives, and cyanoacrylate adhesives.

The laser sub-assembly 102 can be configured with the TEC 104 facing an upward position, as depicted in FIG. 4. The laser sub-assembly 102 or any portion thereof can be assembled proximal to the PIC 101. For example, the laser sub-assembly 102 can be passively aligned along with the PIC 101. More specifically, the laser sub-assembly 102 can be aligned passively in front of a waveguide of the PIC 101 by using a fiducial on the PIC 101 and the laser sub-assembly 102. Once aligned, any of the TEC 104, optical train 105, laser emitter 152, a thermistor, a wavelength locker, can be connected to the PCB 103. For example, any portion of the laser sub-assembly 102 and/or the PIC 101 can be coupled in electrical communication with the PCB 103 via an electrical connection mechanism. The electrical connection mechanism can be a wire bond pad. As used herein, a wire bond pad or simply a pad can be an area on any portion of the laser sub-assembly 102 or PIC 101 configured to provide a connection point for wire bonding. In some aspects, the TEC 104 can include one or more wire bond pads on any portion thereof configured for wire bonding, and more generally electrical communication. In example, the TEC 104 can include one or more wire bond pads disposed on the top portion 104a of the TEC 104 distal to the optical train 105. Metal traces can be connected by way of the vias 206 or alternatively wrap around metallization. Of note, while described as wire boding, other approaches are also contemplated such as a soldered flex or a connector.

The second lens 155 can be a focusing lens. The second lens 155 can be actively aligned to the PIC 101 by using an optical feedback generated from any of an on-chip photodiode, grating couplers, or transmissions to a previously attached fiber. It should be noted that any optical alignment referenced herein can include alignment with the laser path 112 (shown in FIG. 1). Further, the optical alignment referenced herein may also include alignment of the second lens 155 to directly couple the laser in the PIC 101. The second lens 155, or any portion of the optical train 105 can be snap cured via an adhesive in place. In typical aspects, the laser sub-assembly 102 can be configured to be releasably couplable to a full thickness PIC 101, such as a PIC 101 being about 700 micrometers in height. If the PIC 101 is less than 600 micrometers in height, the laser sub-assembly 102 can include the periscope 156 (shown in FIG. 1). The periscope 156 (shown in FIG. 1) can be a device disposed in the laser path 112 which can translate the laser path 112 from a first axis to a second axis. The periscope 156 (shown in FIG. 1) can be bonded to the PIC 101, such as to an optical facet and can be constructed from a transparent prism with either an internally reflecting geometry or reflective coating on angled surfaces. The periscope 156 (shown in FIG. 1) can be formed of, for example, a glass prism. In some aspects, the laser sub-assembly 102 or any portion thereof can be configured to accommodate a minimum pitch of about 1 millimeter. Additionally, if the PIC 101 requires a tight input pitch, the periscope 156 (shown in FIG. 1) can be used in a horizontal axis and can be bonded to the optical facet of the PIC 101.

An advantage of several aspects of the present disclosure is the reduction or management of thermal cross talk. In fiber optic circuits, thermal cross talk can refer to the phenomenon where heat generated by components in the circuit unintentionally affects the performance of nearby components. Such thermal crosstalk can result from localized heating, thermal expansion, temperature-dependent optical properties, and can encourage signal degradation, wavelength shift, increased noise, and component failure. Aspects of the present disclosure can be configured to address power dissipation from the PCB 103 and the crosstalk between TECs 104, should the laser assembly 100 be configured with multiple TECs 104. The laser assembly 100 can include a TEC lid 401. The TEC lid 401 can be configured to extend across the two or more TECs 104.

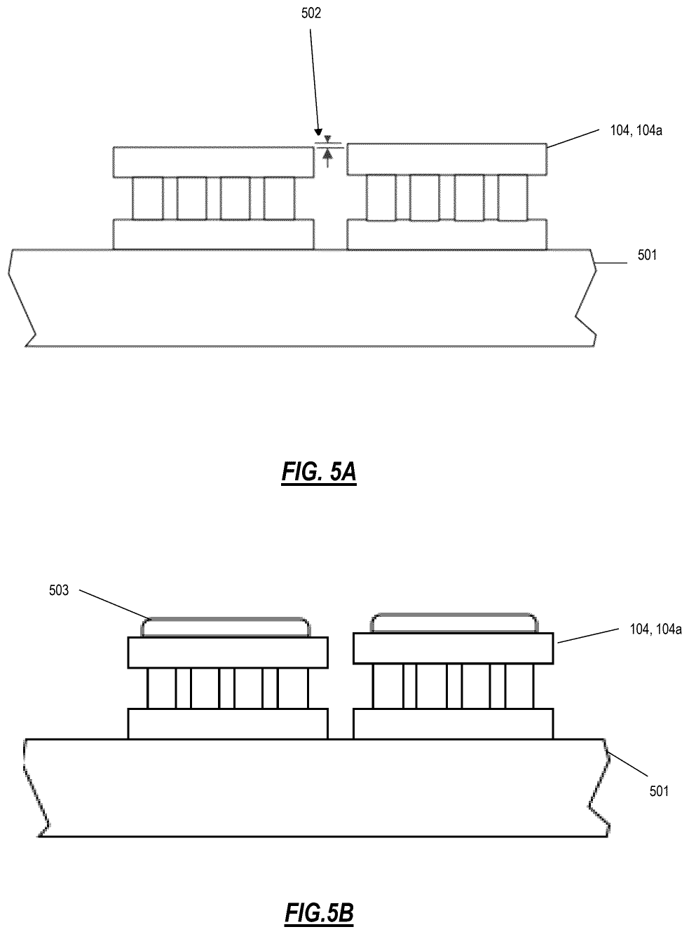

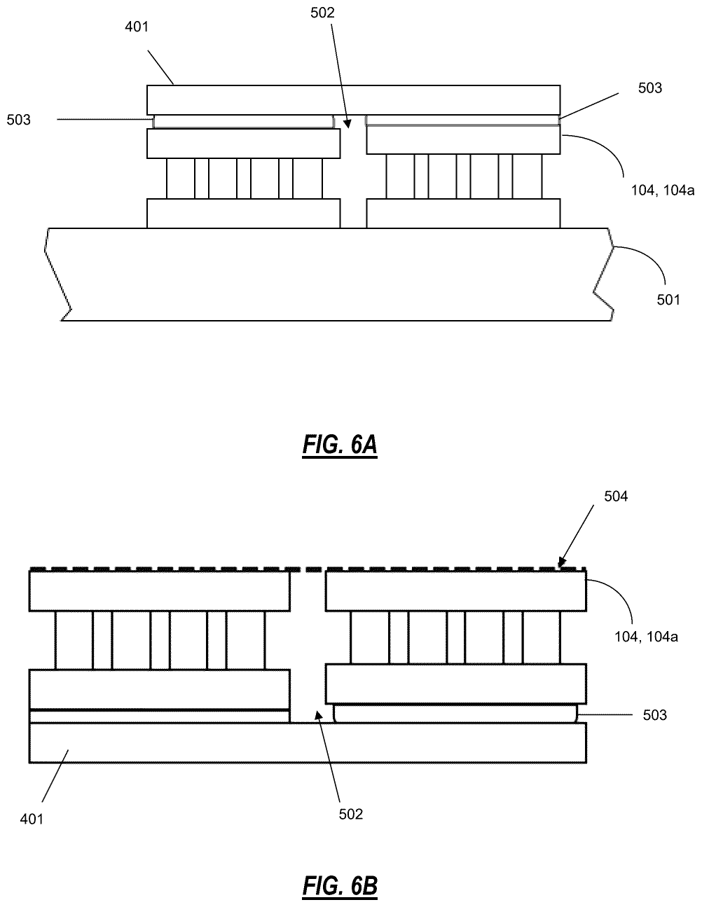

Turning now to FIGS. 5A through 6B, an example of a plurality of TECs 104 coupled to the TEC lid 401 is shown and described. The TEC lid 401 can extend across the top portion 104a of the TEC 104. The TEC lid 401 can define a substantially flat surface. The TEC lid 401 can be bonded to the TECs 104 via an adhesive 503. The adhesive 503 can be any optical adhesive or cement. The adhesive 503 can be similar to the adhesives used to join portions of the laser sub-assembly 102. Specifically, the adhesive 503 can define a low thermal conductivity. As such, wheresoever the adhesive 503 is disposed, a thermally insulated barrier or layer may be formed. The thermal power which emanates from the PCB 103, or any portion thereof can be isolated from the laser sub-assembly 102 via the insulating or low thermal conductivity adhesive 503. More generally the adhesive 503 can be used on any portion of the laser assembly 100 or laser sub-assembly 102 to perform one or both of adhesion and the formation of thermal boundaries. In addition, the lid 107 (shown in FIG. 2) can be formed of thermally insulating materials and can further create a thermal boundary. As used herein, the term “thermal boundary” refers to a section of a device with low thermal conductivity which establishes regions of lowered or restricted heat transfer.

The TECs 104 can experience a temperature difference therebetween due to for example, the different tuning of a laser chip wavelength, which can be temperature sensitive. For example, relative to each other, there can exists a warmer TEC 104 and a cooler TEC 104. The power coming from the warmer TEC 104 can increase the power needed to cool the cooler TEC 104. Thus, the low thermal conductivity of the adhesive 503 or portion of the lid 107 is functional as it improves the thermal isolation between the two TECs 104. Further, the adhesive 503 used to bond the lid 107 can be applied only across a far edge of the laser sub-assembly 102, which can substantially force heat transfer to travel along a further path and reduce the total heat transfer, similarly to the how the voltage drop of a wire increases with wire length.

The laser assembly 100 can include a reversed TEC 104 package wherein the optical train 105 is mounted below the TEC 104. Typical aspects of the invention are configured such that the laser sub-assembly 102 or any portion thereof is assembled and/or disposed superjacent to the PCB 103. As such, the entirety of the laser sub-assembly 102 can be structured to fit above the PCB 103. The optical train 105 and various components can be packaged to fit above the PCB 103. The laser sub-assembly 102 can be configured to be thermally balanced or athermally balanced by adjusting a geometry of the components and by constructing the device from materials based on the material's thermal properties. In example, the materials from which any portion of the laser assembly 100 can be selected based on the thermal expansion coefficient of the materials. In illustrative example, the side wall 171 of the lid 107 can be made of a material matching the lens material, such as Fernico or Kovar. The wall portion could have a different temperature than the lens (which are cooled). In this case, there is a need to balance the product (temperature)*(height)*(CTE) for each stack

Further, by reversing the laser sub-assembly 102 relative to the PCB 103, the TECs 104 can dissipate heat in a direction extending away from the PCB 103 into the top portion 104a of the TECs 104. The laser sub-assembly 102 can be configured to be directly coupled to the PIC 101 which can remove expensive PM fibers and reduce additional losses from the extraneous optical transition. The laser assembly 100 can be configured to couple varying wavelengths in the PIC 101 through multiple optical ports without being forced to use wavelength or polarization multiplexing. Consequentially, this can allow the laser output of the laser sub-assembly 102 and chip input side to be less complex and cheaper to manufacture. Moreover, the laser sub-assembly 102 can be constructed, tested, yielded, and calibrated outside of a modem/transceiver assembly which can avoid cost increases associated with assembly failures at the modem or transceiver. The laser sub-assembly 102 can be sized to be compact enough to fit in front of the PIC 101, such that the laser path 112 is received by a front section of the PIC 101.

### § 1.3 Assembly

Continuing with FIG. 3-6, an assembly or fabrication example is shown and described without limitation. The laser sub-assembly 102 or any portion thereof can be pre-assembled. The optical train 105 or any portion thereof such as a chip-on-chip carrier laser and thermistors can be installed on a surface of the TEC 104, such as the bottom portion 104b. Electrical communication can be established between any portion of the laser assembly 100 via wire bonding, a soldered flex, a connector, etc. One or more wire bonding pads can be defined on a surface of the TECs 104. Any portion of the laser sub-assembly 102 can be aligned through active or passive alignment. For example, the first lens 153 or collimating lens and/or the isolator 154 can be actively aligned on for example, the TEC 104 and can be adhered thereto. The adhesion can be via a UV based snap-cure adhesive. The adhesive 503 can be applied to the side wall 171 of the lid 107. The side wall 171 can be adhered to the laser sub-assembly 102, and more specifically the bottom portion 104b of the TEC 104. The adhesion of the lid 107 can be included in the pre-assembly. It should be noted that in some aspects, the lid 107 can be disposed distal to the top portion 104a of the TEC 104.

The pre-assembled laser sub-assembly 102 can be flipped such that the bottom plate 172 of the lid 107 extends downwardly. The bottom plate 172 of the lid 107 can be engaged with the PCB 103. More generally, the laser sub-assembly 102 can be passively aligned with the PCB 103 while the bottom plate 172 of the laser sub-assembly 102 is engaged with the PCB 103. In example only, the pre-assembled laser sub-assembly 102 can be adhered to and joined to the PCB 103 via fiducials on the ceramic and PCB 103. From there, the wire bonding pads disposed on the TEC 104 can be wire bonded to a PCB pad. More generally, electrical communication can be established which can provide an electrical path for power and control circuits to the optical train 105. The optical train 105 can define an “on” state and an “off” state, wherein the “on” state defines active laser emission and the “off” state defines the cessation of laser emission. While the optical train is “on” or engaged, any portion thereof can be actively aligned. For example, while the lasers are powered on, active alignment of the first or second lens 153, 155 can take place on the bottom plate 172 of the lid 107.

Some aspects of the present disclosure can relate to the creation of a coplanar optical bench using two or more TECs 104. Two or more TECs 104 can be disposed on a lapped surface 501. The lapped surface can be any external surface having either a lapped finish or a substantially flat surface. Sometimes, the two or more TECs 104 can define a height mismatch 502. The height mismatch 502 can be a difference in height of the top portion 104a of the TECs 104 while disposed on and measured from the lapped surface 501. To correct this, the adhesive 503 can be applied to the top portion 104a of the TEC 10 in varying amounts. In some aspects, the adhesive can define an adhesive layer having an adhesive layer thickness. In example, if a first TEC 104 has a lower height measured from the lapped surface 501 when compared to a second TEC 104, then the adhesive 503 can be disposed thereon and create an adhesive layer having a greater thickness than an adhesive layer on the second TEC 104.

Once the adhesive 503 is applied, the TEC lid 401 can be provided. The TEC lid 401 can be joined to the two or more TECs 104 via the adhesive 503 as shown in FIGS. 5 & 6. The TEC lid 401 can create a second flat surface and can be substantially parallel to the lapped surface 501. The combination of the TEC lid 401 and the two or more TECs 104 can be removed from the lapped surface and rotated upside down which can expose a coplanar surface 504. The coplanar surface 504 can be readily adapted to the laser sub-assembly 102.

### § 1.4 Final Laser Assembly

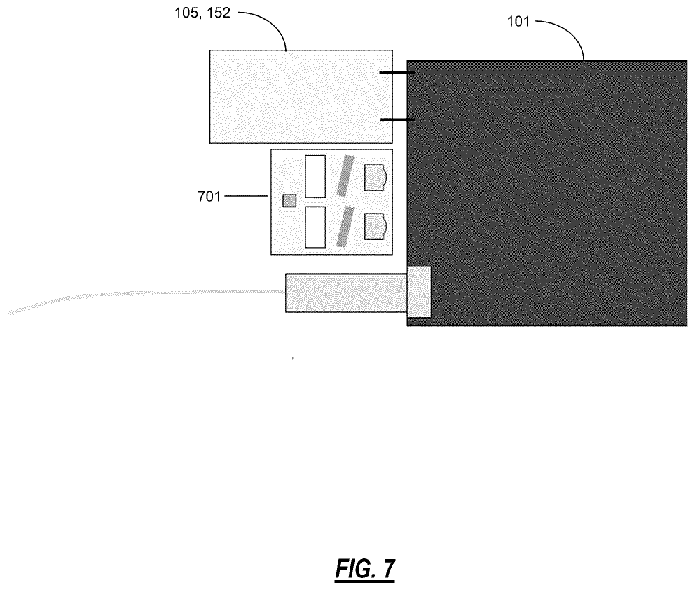

Turning now to FIG. 7, a top-down schematic view of the laser assembly 100 is shown and described. The laser assembly 100 can include an external locker 701. The external locker 701 can define a hollow enclosure and can store therein any portion of the laser assembly 100 and more particularly, the laser sub-assembly 102. The laser sub-assembly 102 or any portion thereof can be pre-assembled or constructed prior to being coupled directly to the PCB 103. Importantly, the pre-assembled laser sub-assembly 102 can be coupled to the PCB 103 “top-down” and directly onto the PCB 103 wherein “top-down” refers to the bottom plate 172 of the lid 107 being in contact with the PCB 103 and the top portion 104a of the TEC 104 extending away from the PCB 103. As a result of such arrangement, the optical train 105, and more specifically the laser emitter 152 can define a laser temperature which can be controlled by the top portion 104a of the TEC 104. The lid 107 of the laser sub-assembly 102 can be the secondary optical bench which can assist in the final alignment of the optical train 105. More specifically, the lid 107 can facilitate the final alignment of the first lens 153 to directly couple the optical train 105 in the PIC 101. In typical aspects, the laser assembly 100 can include a multiplicity of laser sub-assemblies 102 which can each be independently controlled. For example, the multiplicity of laser sub-assemblies 102 can each be independently temperature controlled which can tune the wavelength of each assembly. Such independent tuning can facilitate high optical power.

In typical aspects, one or more portions of the laser assembly 100 can be formed from materials defining a substantially matching thermal expansion such that temperature excursions do not shift the laser beam out of alignment as a result of thermal expansion. The lid 107 and any portion thereof can be a stiffening member which can reduce possible warpage of the optical train 105 due to the softness of the PCB 103. Continuing, the pre-assembling of two or more individual TECs 104 can include incorporating the TEC lid 401 which can mechanically coupled the two or more TECs 104 and define a coplanar axis therebetween. Such creation of the coplanar axis between the two or more TECs can create the coplanar surface 504 onto which the optical trains 105 can be assembled.

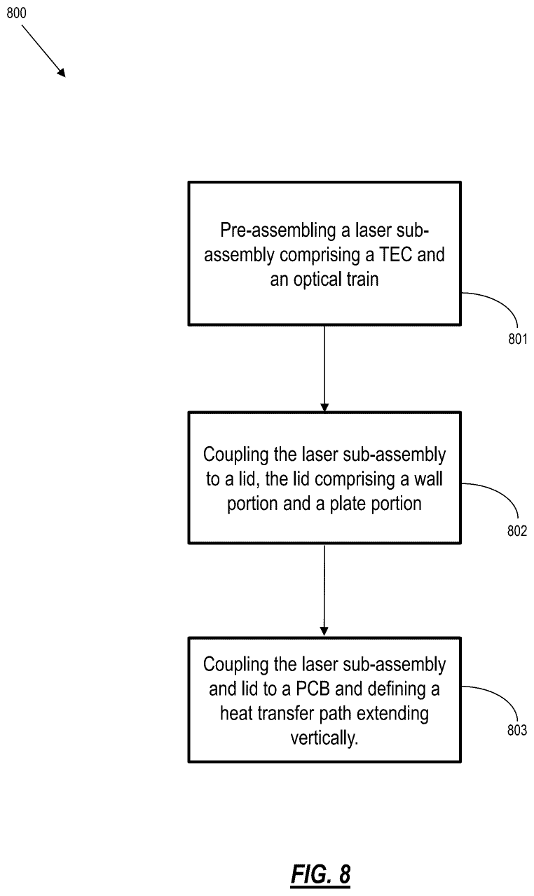

Turning now to FIG. 8, a flowchart for a process 800 for creating the laser assembly 100. The process can include pre-assembling the laser sub-assembly 102 including the TEC 104 and the optical train 105, 801. The process 800 can include coupling the laser sub-assembly 102 to the lid 107, 802. The process 800 can include coupling the laser sub-assembly 102 and lid 107 to the PCB 103 and defining the heat transfer path 110 extending vertically 803.

The process 800 can include wherein the pre-assembling includes optically aligning and adhering the optical train 105 with the TEC 104. The process 800 can include passively aligning the laser sub-assembly 102 with the PIC 101 via one or more fiducials. The process 800 can include electrically coupling the any of the TEC 104, a thermistor, and a wavelength locker to the PCB 103 via one or more wire bond pads on a surface of the TEC 104. The process 800 can include aligning any portion of the optical train 105 to the PIC 101 via feedback from one or both of a photodiode or grating couplers and optionally adhering one or both of the first lens 153 and second lens 155 to the optical train 105. The process 800 can include wherein the laser sub-assembly includes two or more TECs 104 which can be aligned on the TEC lid 401. The process 800 can include wherein the coupling is completed via the adhesive 503, the adhesive 503 is thermally insulative.

### Conclusion

As used herein, including in the claims, the phrases “at least one of” or “one or more of” a list of items refer to any combination of those items, including single members. For example, “at least one of: A, B, or C” covers the possibilities of: A only, B only, C only, a combination of A and B, a combination of A and C, a combination of B and C, and a combination of A, B, and C. Additionally, the terms “comprise,” “comprises,” “comprising,” “include,” “includes,” and “including” are intended to be non-limiting and open-ended. These terms specify essential elements or steps but do not exclude additional elements or steps, even when a claim or series of claims includes more than one of these terms.

While the present disclosure has been detailed and depicted through specific embodiments and examples, it is to be understood by those skilled in the art that numerous variations and modifications can perform equivalent functions or yield comparable results. Such alternative embodiments and variations, which may not be explicitly mentioned but achieve the objectives and adhere to the principles disclosed herein, fall within its spirit and scope. Accordingly, they are envisioned and encompassed by this disclosure, warranting protection under the claims associated herewith. That is, the present disclosure anticipates combinations and permutations of the described elements, operations, steps, methods, processes, algorithms, functions, techniques, modules, circuits, etc., in any manner conceivable, whether collectively, in subsets, or individually, further broadening the ambit of potential embodiments.

Although operations, steps, instructions, and the like are shown in the drawings in a particular order, this does not imply that they must be performed in that specific sequence or that all depicted operations are necessary to achieve desirable results. The drawings may schematically represent example processes as flowcharts or flow diagrams, but additional operations not depicted can be incorporated. For instance, extra operations can occur before, after, simultaneously with, or between any of the illustrated steps. In some cases, multitasking and parallel processing might be beneficial. Furthermore, the separation of system components described should not be interpreted as mandatory for all implementations.

As used throughout, the singular forms “a,” “an,” and “the” include plural referents unless the context clearly dictates otherwise. Thus, for example, reference to a quantity of one of a particular element can comprise two or more such elements unless the context indicates otherwise. In addition, any of the elements described herein can be a first such element, a second such element, and so forth (e.g., a first widget and a second widget, even if only a “widget” is referenced).

Ranges can be expressed herein as from “about” one particular value and/or to “about” another particular value. When such a range is expressed, another aspect comprises from the one particular value and/or to the other particular value. Similarly, when values are expressed as approximations, by use of the antecedent “about” or “substantially,” it will be understood that the particular value forms another aspect. It will be further understood that the endpoints of each of the ranges are significant both in relation to the other endpoint and independently of the other endpoint.

For purposes of the current disclosure, a material property or dimension measuring about X or substantially X on a particular measurement scale measures within a range between X plus an industry-standard upper tolerance for the specified measurement and X minus an industry-standard lower tolerance for the specified measurement. Because tolerances can vary between different materials, processes, and between different models, the tolerance for a particular measurement of a particular component can fall within a range of tolerances.

As used herein, the terms “optional” or “optionally” mean that the subsequently described event or circumstance may or may not occur, and that the description comprises instances where said event or circumstance occurs and instances where it does not.

What is claimed is:

1. A laser assembly, the laser assembly comprising:
a printed circuit board; and
a laser sub-assembly including a thermo-electric cooler and an optical train, wherein the laser sub-assembly is configured to connect to the printed circuit board such that the optical train is disposed between the printed circuit board and the thermo-electric cooler,
wherein the thermo-electric cooler is configured to extract heat from the optical train outwardly from the printed circuit board, and
wherein the laser assembly is configured to connect optically with a photonic integrated circuit via free space.

2. The laser assembly of claim 1, wherein the optical train further includes any of a first lens, a second lens, and an isolator disposed in a laser path of the optical train.

3. The laser assembly of claim 1, further including a periscope disposed in a laser path of the optical train, wherein the periscope is configured to adjust the laser path based on a misalignment between the optical train and the photonic integrated circuit.

4. The laser assembly of claim 1, wherein the thermo-electric cooler is structured as a first optical bench configured for optical alignment.

5. The laser assembly of claim 1, wherein the sub-laser assembly is connected to the printed circuit board via a lid including a wall portion and a plate portion, the lid defining a resilient structure sized to encase a portion or all of the laser sub-assembly.

6. The laser assembly of claim 5, wherein the lid is structured as a second optical bench configured for optical alignment.

7. The laser assembly of claim 5, wherein the lid is configured to provide structural support for the laser assembly when connected to the printed circuit board.

8. The laser assembly of claim 1, further including at least one pad disposed on a surface of the thermo-electric cooler configured to provide electrical communication between one or more portions of the laser assembly.

9. The laser assembly of claim 1, wherein any of one or more components of the laser sub-assembly, the photonic integrated circuit, and printed circuit board define an effectively substantially similar coefficient of thermal expansion.

10. The laser assembly of claim 1, further including a thermistor and/or a wavelength locker in electrical communication with the photonic integrated circuit or another integrated circuit.

11. The laser assembly of claim 1, wherein the laser sub-assembly further includes a plurality of optical trains, each optical train is configured for independent temperature control via the respective thermo-electric cooler.

12. The laser assembly of claim 1, further including a thermally resistant adhesive configured to join any portion of the laser assembly and provide selective thermal insulation.

13. The laser assembly of claim 1, wherein the laser assembly is pre-assembled prior to being connected to the printed circuit board.

14. A laser assembly on a printed circuit board formed by a process comprising steps of:
pre-assembling a laser sub-assembly including at least one thermo-electric cooler and at least one optical train;
coupling the pre-assembled laser sub-assembly on a lid to the printed circuit board, such that the optical train is disposed between the printed circuit board and the thermo-electric cooler; and
optically coupling the laser sub-assembly to a photonic integrated circuit via free space;
wherein the thermo-electric cooler is configured to extract heat from the optical train outwardly from the printed circuit board.

15. The laser assembly of claim 14, wherein the pre-assembling includes optically aligning and adhering the optical train with the thermo-electric cooler.

16. The laser assembly of claim 14, further including the step of aligning the laser sub-assembly with a photonic integrated circuit.

17. The laser assembly of claim 14, further including the step of electrically coupling the thermo-electric cooler to the printed circuit board via one or more pads disposed on a surface of the thermo-electric cooler.

18. The laser assembly of claim 14, further including the steps of aligning one or more optical devices including lens with the optical train and the photonic integrated circuit.

19. The laser assembly of claim 14, wherein the laser assembly includes two or more thermo-electric coolers.

20. The laser assembly of claim 14, wherein the coupling includes adhesion with a thermally insulative adhesive.
